(19) United States
(12) Patent Application Publication
(10) Pub. No.: US 2017/0104297 A1
(43) Pub. Date: Apr. 13, 2017

(54) USB Lamp Base

(71) Applicant: Plugg Home Innovations LLC, Las Vegas, NV (US)

(72) Inventors: Jonathan Silver Scott, Las Vegas, NV (US); Andrew Alfred Scott, Las Vegas, NV (US)

(73) Assignee: Plugg Home Innovations LLC, Las Vegas, NV (US)

(21) Appl. No.: 14/882,431

(22) Filed: Oct. 13, 2015

(51) Int. Cl. H01R 13/66; H01R 25/00; H02J 7/00; F21V 27/00; H05K 5/03

(52) U.S. Cl. CPC H01R 13/6675; F21V 27/00; H05K 5/03; H02J 7/0052; H01R 25/003; H02J 2007/0062

(57) ABSTRACT

In one embodiment, the present apparatus provides weight-bearing support for a lamp, while providing electrical connectivity by one or more USB ports. The apparatus may comprise a base, a wall, and a lid with a top surface. One or more parts may be molded as one and connected to one or more of the other parts using any selection or combination of threads, click-in-place mechanisms, or the like. The apparatus may be made of any appropriate material, such as a metal or metal alloy, plastic, or a combination of materials.

### TECHNICAL FIELD

The present invention is generally related to the field of electrical devices, and, more particularly, to a lamp base configured to serve as a power supply and charging station.

### BACKGROUND

Even in today's wireless technological environmental, users of portable electronic devices rely on wired connections of their devices for charging and various other purposes on a regular if not daily basis. These devices include cell phones and smartphones, tablets and e-readers, portable hotspots and portable speakers, external charging batteries, GPS devices and cameras, as well as a multitude of other portable devices capable of being recharged via a USB or other known connection.

However, these devices must be charged regularly, which makes for an inconvenient task. Opportunities to charge throughout the day are unpredictable. When an individual is at work or returns home, he or she must capitalize on any or all available wall outlets; however, wall outlets are almost always limited to two discrete outlets, and this is often not enough for all of an individual's devices, let alone the multiple individuals that may be sharing the same space.

If a user leaves home without a charged device, that user will eventually find himself or herself unable to use the wireless portable device to its full extent for one reason or another. Accordingly, users will develop systems or routines for regularly charging devices. Typically users will keep various AC converters or power adapters, suitable for each device, plugged into power outlets around one's home or office. Or a user will have unsightly power outlet strips or surge-protectors unceremoniously sitting on the floor or on furniture nearby a precious open wall socket outlet.

Users sometimes will overload that scarce open wall socket with a socket multiplier only to find that the bulky size of the requisite AC converters or power adapters blocks access to the added outlets. Even with a surge protector providing a greater number of outlets, the outlets are often situated in an inconvenient place, such as under desks or behind furniture. Furthermore, many outlets on the surge protector are frequently used for powering other electronic devices or components, such as TVs and other AV components, computer and printers or other computer peripherals, or lamps and cordless phones.

Even charging ones phone at night is a small ordeal as a user reaches over the bedside nightstand to access the wall socket found behind the furniture, while realizing that the ubiquitous and outlet hogging alarms clock and table lamp sitting on the nightstand have claimed that outlet space generations ago. Moreover, alarm clocks and other devices with charging docks incorporated in them often suffer the invariable fate of having the dock become obsolete by new and improved models of the devices, or must rely on unstable and inconvenient adapters.

The fact that the AC converters or power adapters have shrunk in size over time only helps to the extent outlets are available. And while these devices are capable of eschewing AC converters or power adapters in favor of a direct USB connection, this is only helpful to extent a user has an open and powered USB port available. Typically a USB port on a laptop is only powered while the laptop is powered on. The ability to charge via a USB port is often limited to the time a user is actively using his computer. Or if a dedicated USB hub is purchased, that hub is yet another unsightly device on ones desk with other USB cables powering a mouse, or a keyboard, or a printer, or other computer peripherals permanently emanating from it. The increasing popularity and availability of portable electronic devices has resulted in an increasing demand for a convenient, elegant, and technologically up-to-date solutions for a user to charge his electronic device without crawling under or behind furniture while maintaining one's uncluttered living or working environment.

Accordingly, there is a need for a more convenient charging option, one that may provide greater accessibility, thereby allowing the user to plug in and plug out without having to bend behind or below furniture. This charging option may also reduce the problem of having lamps or other electronic devices or fixtures occupying the available outlets without resorting to devices that take up desk or table space or that look inelegant or interfere with ones décor, but rather one that can integrate into ones existing decor.

### SUMMARY

The present apparatus provides weight-bearing support for a number of devices, including a lamp. Also, the apparatus provides electrical and perhaps data connectivity to one or more devices, such as smart phones, mp3 players, and other portable devices that require charging. The apparatus may itself be powered electrically through a cable plug and wall-outlet system, or by a rechargeable or replaceable battery.

The apparatus may be structurally made of a base, a wall, and a lid, althought other embodiments are possible as well. The base provides a contact area for the surface on which the apparatus rests, and that contact may be either immediate or mediated by knobs, pads, or other support components. These support components may be height-adjustable, so that a user of the apparatus can control the proximity between the surface on which the apparatus sits and the base. They may also provide protection for the surface against scratches or dents. The lid provides a contact area for the object(s) placed on top of the apparatus, and connects externally to the base by the wall. The lid and side walls may feature ornamentation, such as designs or textures, or fixtures providing certain functional advantages, such as means to hold wires in place, etc. In some embodiments, the apparatus is fitted with USB ports, data ports and/or electrical outlets of various kinds. These outlets may conceivably be fitted for any international standard or voltage levels, and may include grounding channels. Control of the electrical components may be available to the user in the form of any number of buttons or switches.

The base, wall, and lid may be molded together as one piece. Alternatively, one or more parts may be molded as one and connected to one or more of the other parts using any selection or combination of threads, click-in-place mechanisms, or the like. The apparatus may be made of any appropriate material, such as a metal or metal alloy, plastic, or a combination of materials.

### BRIEF DESCRIPTION OF THE DRAWINGS

FIG. 1 provides an aerial front view of an embodiment of the apparatus.

FIG. 2 provides an aerial back view of an embodiment of the apparatus.

FIG. 3 provides a front view of an embodiment of the apparatus.

FIG. 4 provides a back view of an embodiment of the apparatus.

FIG. 5 provides a side view of an embodiment of the apparatus.

FIG. 6 provides an alternative side view of an embodiment of the apparatus.

FIG. 7 provides a top view of an embodiment of the apparatus.

FIG. 8 provides a bottom view of an embodiment of the apparatus.

FIG. 8a provides a bottom view of another embodiment of the apparatus.

FIG. 8b provides a bottom view of an embodiment of the apparatus illustrated in FIG. 8a in use.

FIG. 8c provides a bottom view of another embodiment of the apparatus.

FIG. 8d provides a bottom view of an embodiment of the apparatus illustrated in FIG. 8c in use.

FIG. 9 provides an aerial view of an embodiment of the apparatus in use on a tabletop.

### DETAILED DESCRIPTION

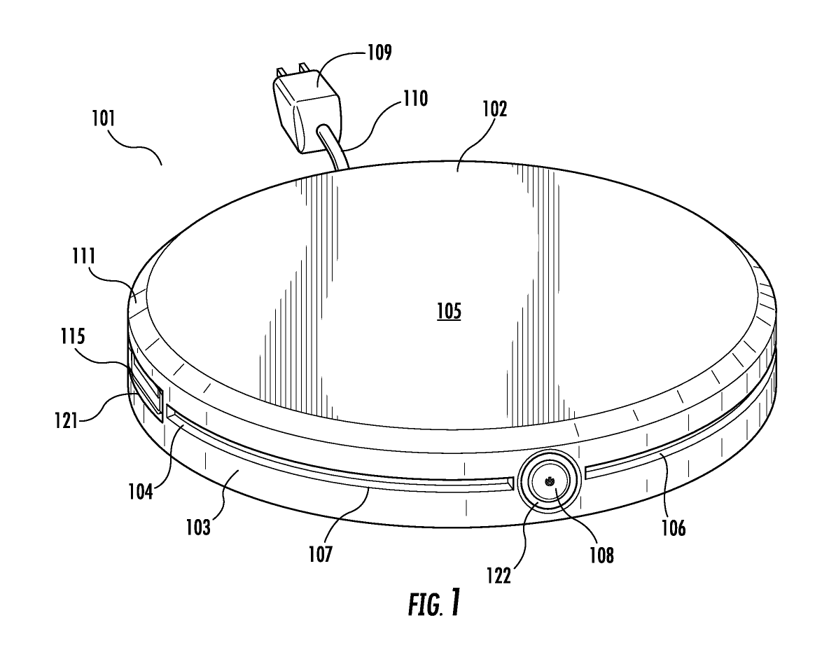

FIG. 1 discloses an embodiment in which apparatus 101 comprising a lid 102, at least one wall 103, at least one groove section 104, and a bottom 116. The wall 103 may be attached to the lid 102 or it may be attached to the bottom 116 in an embodiment. The lid 102 features a top surface 105, and may include a bevelled section 111. Although in other embodiments the top surface of the lid 105 and the wall 102 may meet at right angles to each other, and in other embodiments, the top surface 105 and the wall 102 may meet at a rounded corner.

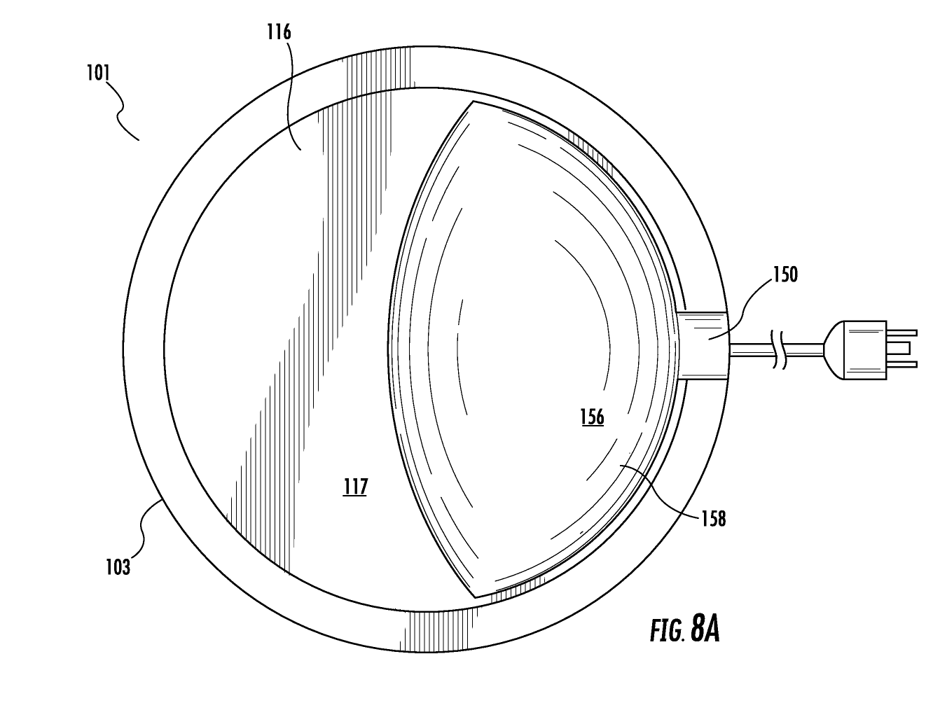

An aerial view of top surface 105 can also be seen in FIG. 7. In this view, the lid is circular and thus the wall is in the form of a circle as well. However, in other embodiments it is contemplated that the apparatus 101 be configured in different geometrical shapes, such as square, rectangular, ovular, polygonal, as well as combinations thereof; also, the shape may be symmetrical or asymmetrical. Accordingly, the apparatus is not limited to a single wall. In order to match the shape of the lid, or for other reasons disclosed below, the apparatus may comprise one or more walls. The lid 102 may be separable from the apparatus 101, in whole or in part, by a user allowing access to an interior portion of the apparatus.

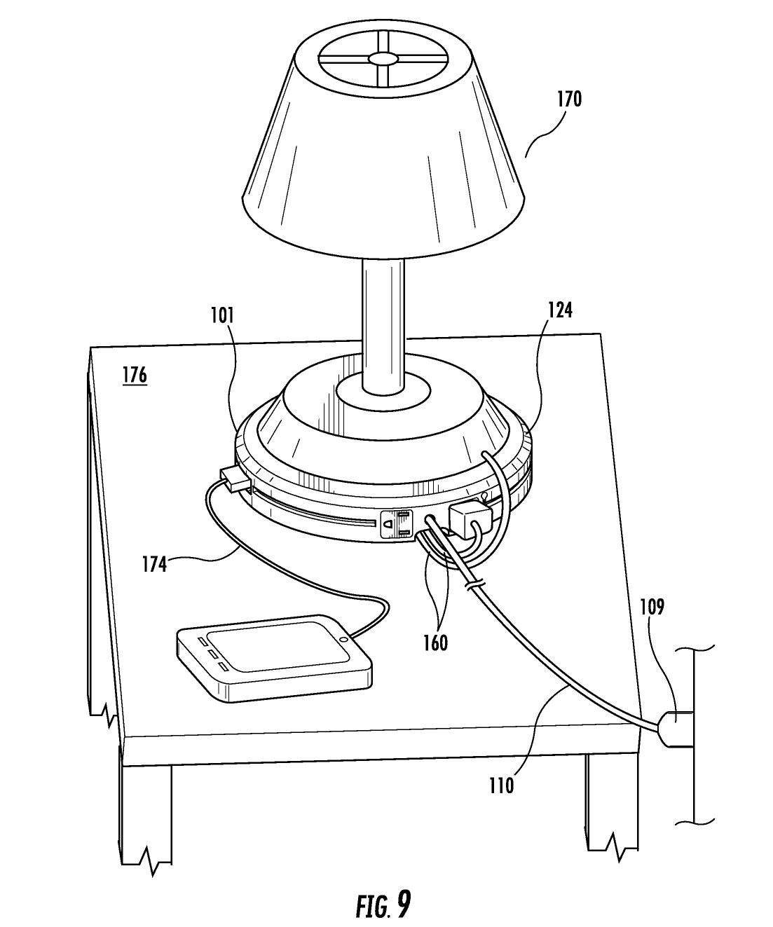

The top surface of the lid 105 may receive and support the weight of another object, such as a lamp 170 (FIG. 9). The shape of the lid may be configured to complement the shape of base of an existing lamp. Thus, to support a lamp 170 having a circular base, an apparatus 101 with a circular shaped lid may be used as illustrated in FIG. 9, but for use with a lamp with a square base, an apparatus 101 with a square lid may be used.

The apparatus 101 may be made of various materials to best complement the design an existing lamp under which it will sit and to have sufficient strength to support the weight of a lamp. The apparatus 101 may also come in numerous colors, textures and surfaces, also to best complement the design an existing lamp under which it will sit. A user may wish the apparatus to blend in and be unnoticed. A user may also wish the apparatus to be an accent to an existing lamp. No limitation on the on the aesthetic result on the apparatus 101 and lamp 170 combination is intended.

The top surface 105 may be substantially flat, free of obstructions, and greater than three inches in diameter. In another version, the top surface 105 is greater than five inches in diameter. In one embodiment, the lid comprises one or more magnets to magnetically couple with an object placed upon it. In another embodiment, the lid comprises one or more protrusions. These one or more protrusions may be shaped and/or positioned so as to help secure the object placed on top of the lid. In yet another embodiment, the lid comprises one or more areas of texture. The texture may be jagged and random, such as gravel or sand textured, or comprise a pattern such as ridges or cocentric circles, or even a combination thereof, such that a geometical pattern is created using a jagged surface. The texture and pattern increases the friction that must be overcome before an object placed upon the lid can slide off the lid. Additionally, the texture may be ornamental.

In one embodiment, the one or more walls comprise one or more openings that facilitate access to the interior of the apparatus, including an electronics portion. In some versions, these opening can be configured to be fitted with one or more USB or data ports 115 electrical outlets or plugs 112, 152, switches to operate or control the apparatus 108, charging or power cables 110, or openings 150 to provide access to a compartment, cavity or recess internal or underneath the apparatus 101 in which to gather and/or hide charging/data cables 174 or power cables 160. In some versions, these openings may be closeable. For example a sliding door may be disposed behind a wall and adjacent to an opening, where the sliding door features a tab or uneven surface accessible to a human finger or a device such as a pen, such that the sliding door can be slided across the opening. Other door or closing methods known in the art are also contemplated. These doors may help protect the opening from dust and debris, or may be used to provide a cleaner appearance to the apparatus to help it blend into the existing décor rather than appearing like a utilitarian charging device. In some versions, these one or more openings are “framed” or bordered by rubber, plastic, or other partially cushioning material 121, thereby preventing the part of the wall 103 that surrounds the openings from scratching, cutting, or otherwise damaging human fingers or other objects placed into or adjacent to the openings. The frames 121 may also provide an ornamental value to the apparatus and/or an electrically inductive barrier. Further, the frames 121 may provide a buffer between the opening and an electrical component accessible through the opening, in order to balance or minimize inaccuracies made during the manufacturing process.

The openings that house the USB or data ports 115 may be disposed on a wall 103 at any location of the apparatus 101, however, in an embodiment, the USB or data ports may be located on a side of the apparatus 101 so as to be less visually conspicuous than if directly in the front of the apparatus, but still easily accessible to a user. There may be one or more USB or data ports on the apparatus. In an embodiment the apparatus may have one USB port 115 on each side. However, this disclosure contained no limitations as to the number and location of the USB or data ports. Cables 174 for charging or data transmission may be plugging into the USB or data ports 115.

The apparatus 101 may also have one or more switches 108 to control the operation of any of the electronic connections of the apparatus 101. In an embodiment, a switch 108 may be located near the front of the apparatus, embedded in a wall 103, or embedded in the lid 102, so as to be easily accessible by a user. The switch may control one or more an electrical outlets or plugs 112, 152 into which a user may connect the lamp or other electronic device. In this embodiment, the user may then control the lamp 170 by the switch 108 on the apparatus 101 and thus not have to reach under the lamp shade or otherwise search for the lamp switch. This switch 108 may be surrounded by a light emitting border or integrated with a light emitting region or point 122 at least partially located on the exterior and/or center of the switch. The one or more switches may have discrete on/off sections, or they may be punch switches, such that pressing the same area of the switch alternately turns the switch on and off. In an embodiment, the switch 108 may be dedicated to just one outlet 112, where this outlet may be configured to receive the plug from the lamp. In this embodiment, outlet 112 may be surrounded by a light emitting border or integrated with a light emitting region or point, or perhaps labeled with a light bulb insignia 172 or otherwise labeled to indicate to a user that it is a dedicated outlet for the lamp.

In one embodiment, the one or more USB ports 115 and electrical outlets 112, 152 are electrically connected to a power supply, possibly a surge protector residing in the interior of the apparatus. This power supply may comprise a replaceable battery, a chargeable battery unit, and/or an electrical plug and cable 109,110 that may coupled with a wall outlet. In one version, the power supply may also be controlled by a user of the apparatus by one or more switches 108. Turning off the power supply of the apparatus 101 would allow a user to control the amount of stand-by or “phantom” power the apparatus, or plugged in devices may consumed when not actively in use or charging. The electrical plug and cable 109,110 may be located on a back side of the apparatus 101.

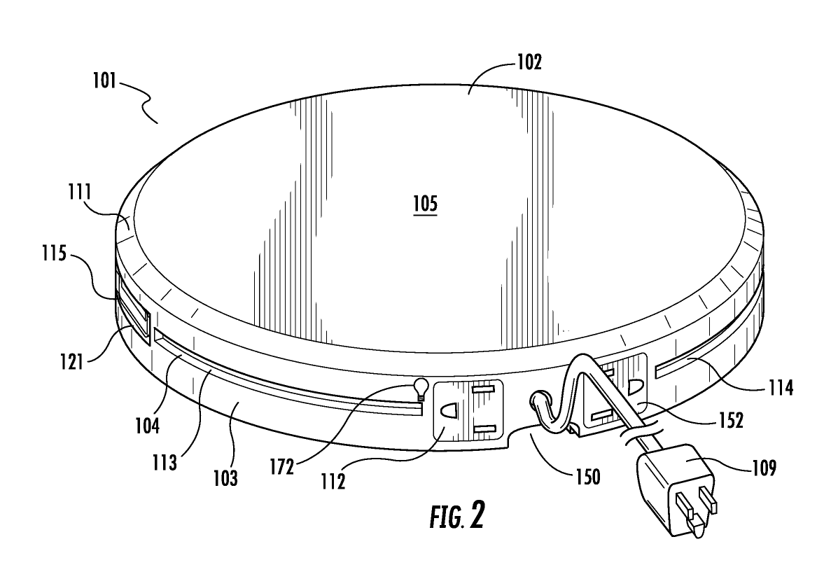

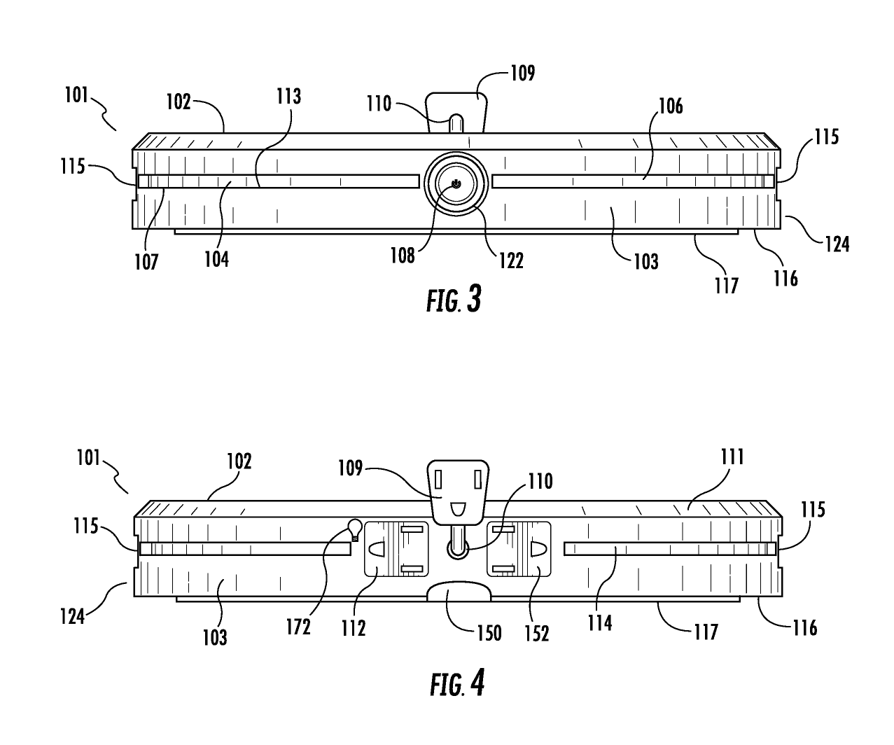

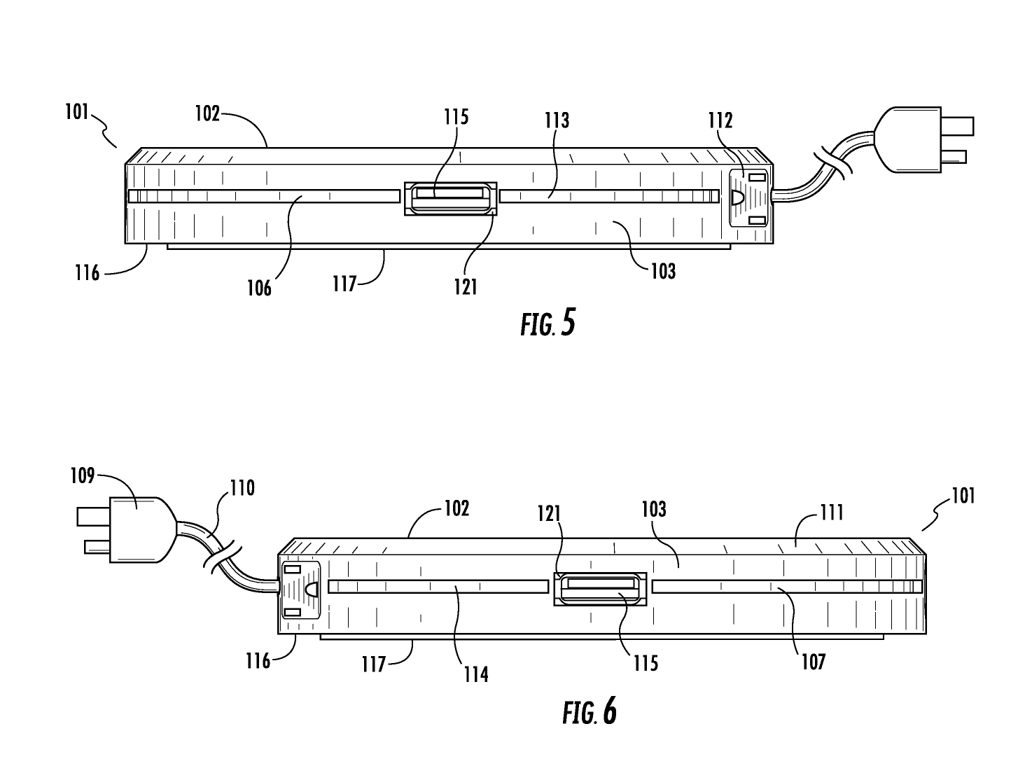

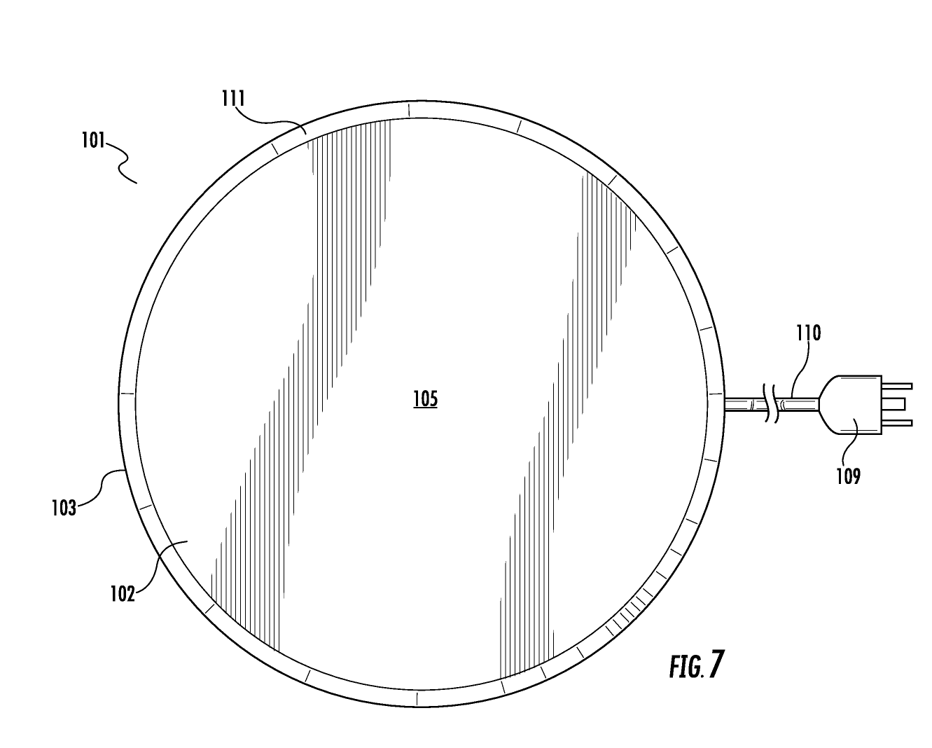

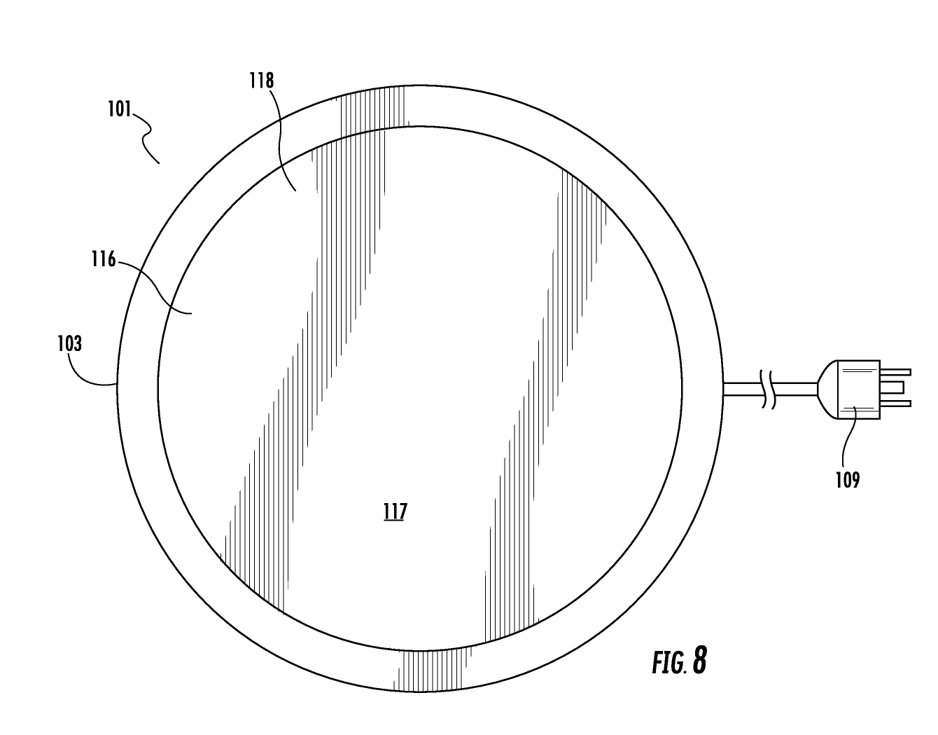

In one embodiment, the apparatus may comprise one or more groove sections 104 disposed in one or more walls 103. A groove section is a recess disposed at least partially circumferentially or along the perimeter of a wall. Multiple groove sections may be spaced apart such that each occupies a seperate arc or perimeter section broken up for one of the openings 106,107,113,114. In one version, one or more openings are disposed within one or more groove sections such that the groove is not broken up into portions by the opening. This may allow a USB port 115, or other data port to be visually more hidden than otherwise, once again providing the apparatus 101 a more finished appearance, blending into the existing décor rather than appearing like a utilitarian charging device. FIGS. 5-6 disclose an embodiment in which a USB Port 115 is disposed between two groove sections 106,113 and 107,114 respectively. FIG. 1 discloses that the groove section may be split into at least two sections, 106 and 107 having disposed on the wall and between the two groove sections a button 108, which may be responsible for turning on one or more electrical components located within the apparatus. FIG. 2 discloses that the groove section may be split into at least two sections, 113 and 114 having disposed on the wall and between the two groove sections outlets 112, 152 and plug and cable 109,110, for powering the lamp and another 120V device, as well for powering the apparatus 101 itself.

Electrical plug 109 is attached to electrical wire 110, which may be disposed within the apparatus 101 and may emerge from a wall 103. Electrical plug 109 may be plugged into an outlet (FIG. 9) to power the apparatus. FIG. 2 discloses an embodiment in which electrical wire 110 is partly disposed within the apparatus and emerges from the apparatus through an opening in wall 103 disposed between outlets 112 and 152. Electrical cable 110 may also be retractable and thus hidden within the interior of the apparatus or may have a compartment within the apparatus where the cable may be stored.

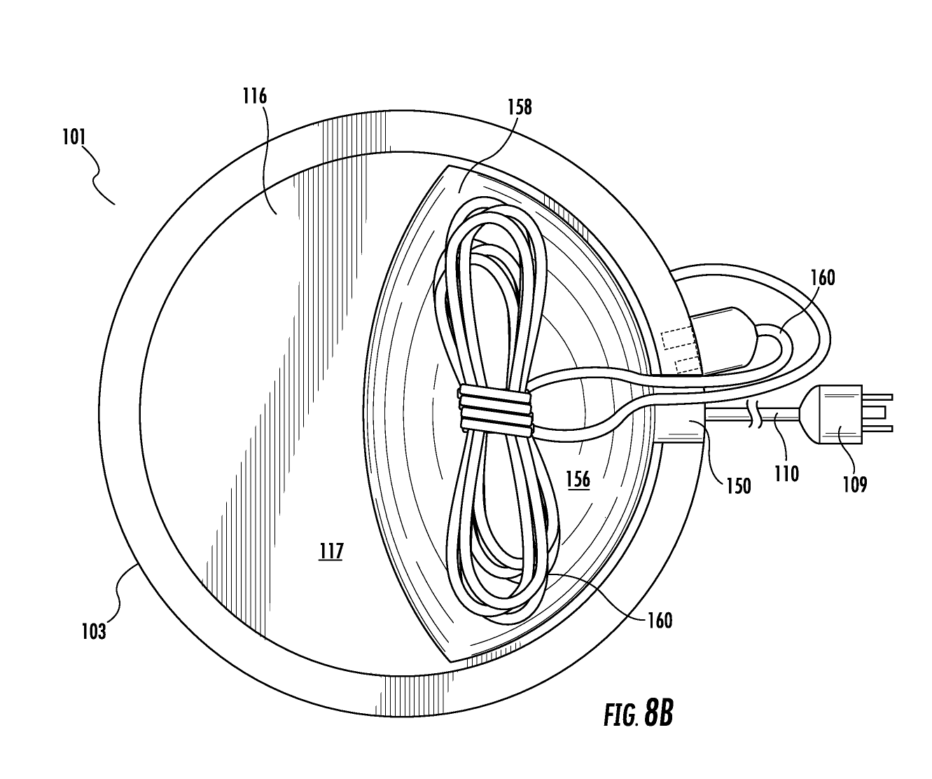

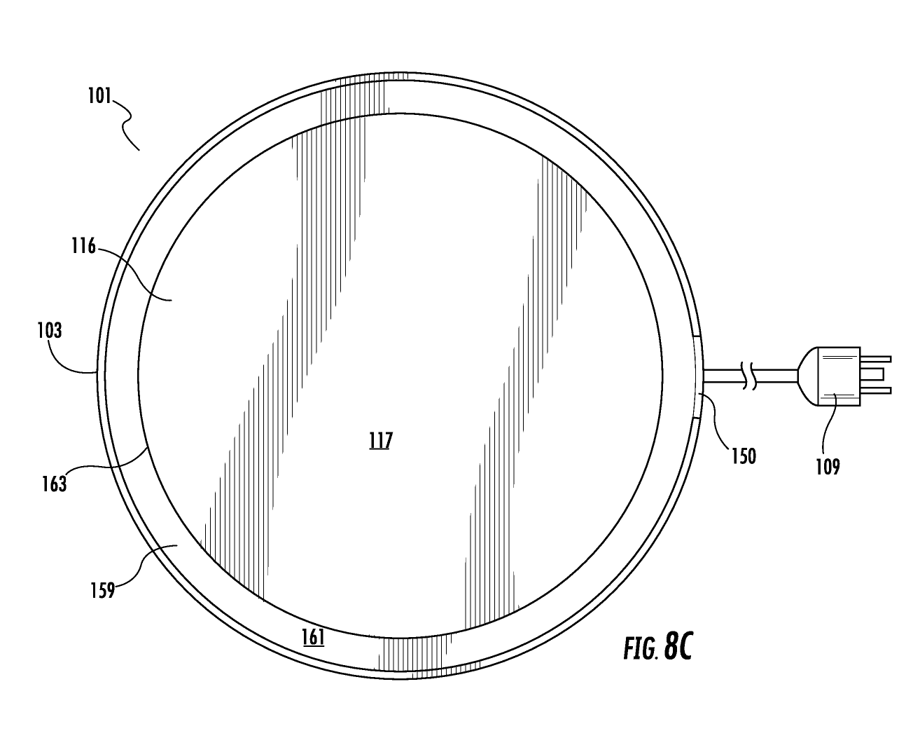

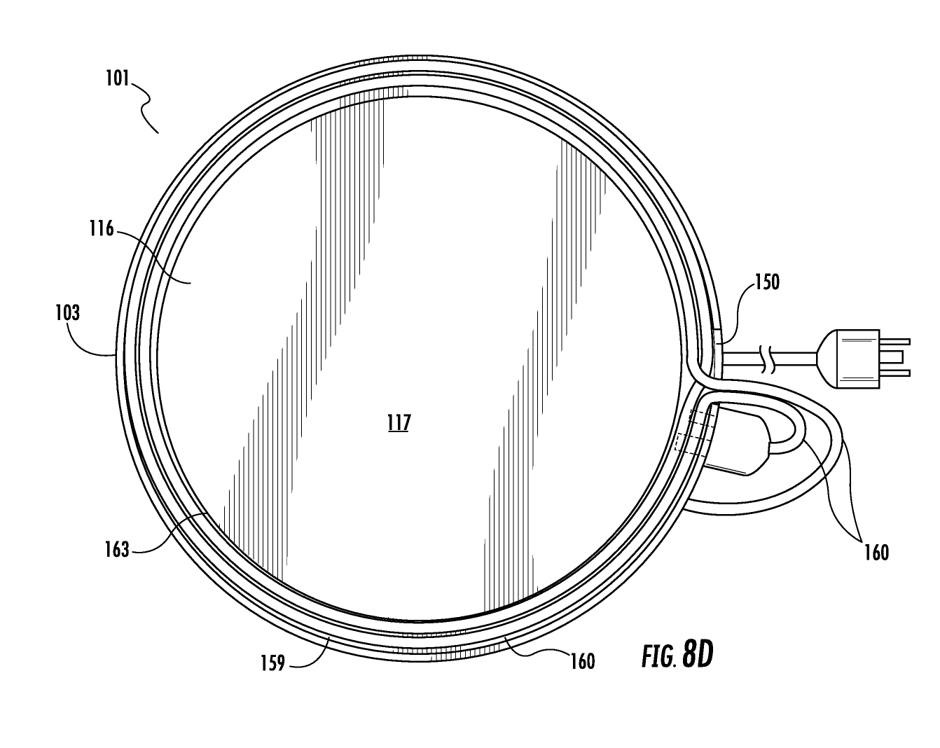

FIG. 8 discloses an embodiment in which the apparatus 101 comprises a bottom 116 with a bottom surface 117. The bottom surface may comprise a soft pad 118. One or more soft pads disposed on the bottom surface may prevent scratching or otherwise damaging the flat surface. Additionally or alternatively, the soft pads in this embodiment have a high-friction texture to prevent the base from slipping off the flat surface.

As described herein, cavities or compartment may be disposed within the interior or beneath the apparatus. These cavities of compartments may be access directly from the bottom of the apparatus. FIG. 8a illustrates such a cavity 158 having a top cavity surface 156. Cavity 158 is disposed and sized to contain a portion of a cable used with the apparatus while leaving sufficient interior room for the apparatus to house all necessary electronics. Cavity 158 may also be closed from the bottom, access via a door or gate in the apparatus through bottom 116 or wall 103. The cavity may also be completely closed off at bottom 116, and accessed laterally through a wall opening 150 or an opening in the top surface 105.

FIG. 8b illustrates the embodiment shown in FIG. 8a with a lamp cable 160 coiled and stored in cavity 158 while the lamp is plugged into outlet 112 for power. Lamp cable 160 may fit through an opening 150 in wall 103 so that the apparatus may sit flat while a cable is kept in the cavity. In FIG. 8b, the lamp cable 160 is shown entering the cavity 158 via an opening 150, where excess cable may be gathered, but allowing the ends of the cable to exit at an opening 150.

Such cavities may also be disposed at other places around the apparatus to similarly hide/store other cables that may be used. In another version, the one or more opening 150 in the wall 103 may be provide access to the interior of the apparatus along a portion of the perimeter of the apparatus, such that a wire or cable can be translated through a length of the opening 150 into a cavity 158 or compartment within the apparatus.

In another embodiment, the apparatus may comprise an inner compartment such as cavity 158, but closed off by bottom 116. The compartment may comprise a recess or a gate. The gate may be hingedly or slidably attached to one or more walls, the base (to be discussed below), and/or the lid. The gate may comprise an opening that extends to an edge of the gate, such that a wire or cable can be inserted or slided through the opening and into the recess of the compartment; thereafter, the gate may close over the recess, thereby neatly organizing and hiding a substantial portion of the wire or cable.

In one embodiment, the lid 102 may comprise of one or more openings. In an embodiment, the apparatus 101 may have a top surface area greater than that of the base of a lamp 170. Space on the lid 102 may be provided for one or more plugs to be disposed on the surface 105 for the lamp to plug into. This space maybe configured to be behind the lamp 170 to make it less obvious to an observer and help the apparatus 101 blend in to the existing décor. In an embodiment the lid 102 surface 105 may also have an opening for a compartment or cavity in which to stash the lamp cable or other cables. A closable compartment that may be used to gather up excess wire or cable from the lamp may have an opening in a wall 103 as well.

In another embodiment, a wall may be either a side wall or an interior wall. In an embodiment, one or more interior walls may be dimensioned to conform and fit substantially flush within one or more side walls 103, such that the interior walls are closer to the interior of the apparatus while the side walls form part of the exterior of the apparatus. In a further version, the interior walls 163 and side walls 103 are substantially concentric or otherwise dimensioned to conform, but they are not flush with one another; rather, they are spaced apart so that a cable wrapped or gathered within one or more interior or side walls and yet between interior and side walls as illustrated in FIGS. 8c and 8d. Access to this inner cavity 159 between exterior 103 and interior 163 walls may be through openings 150 in the side wall 103. Cavity 159 may have an inner upper surface 161.

In FIG. 8d, the lamp cable 160 is shown entering the cavity 159 via an opening 150, where excess cable may be wound around the interior of the apparatus, but allowing the ends of the cable to exit at openings 150. On end attaches to the lamp and the other end may plug into the apparatus at outlet 112.

The cavities, recesses, and compartments disclosed herein may also be accessed via closable opening in the side wall, or via openings in the surface 105 of the lid 102 or via openings in the lower surface 117 of the bottom 116. Opening 150 may be completely surrounded by the wall 103, or may be formed such that the wall does not meet the bottom 116 over a lateral distance forming the opening as an archway in the side wall.

In another embodiment, the interior walls 163 are rotatably aligned with the side walls 103, such that an axis of rotation passes through the center of the apparatus 101 perpendicular to the bottom 116. In this embodiment, the interior walls may be rotated so as to close the one or more openings of the side wall or close access to one or more cavities, recesses, and compartments.

In another embodiment, one or more sets of two protrusions may be disposed on one or more walls. In this embodiment, two or more two protrusions are spaced apart such that a wire or cable can be snugly fitted between them, yet can be removed if a little force is used when pulling the wire or cable in order to temporarily deform one or both of the set of protrusions.

In yet another embodiment, a flange may be disposed at least partly around one or more walls. This flange may comprise a lip, such that the flange extends substantially perpendicularly from one or more walls, and the lip extends substantially perpendicularly from the flange, thereby enabling a device, such as a smartphone, to be placed upon the flange, rested against a wall, and secured by the lip. This flange may be retractable, through a spring loaded mechanism or other known method, so that the flange may be hidden when not in use.

FIG. 9 discloses an embodiment in which the apparatus comprises a base for a lamp on which a lamp may be placed 124, which is positioned on a separate surface, such as a table top 176. The base supports the weight and structure of the apparatus. Also, the apparatus provides a bottom surface that may sit substantially flush against a flat surface, such as a table, or specifically, a nightstand.

In one embodiment, one or more feet are disposed on the bottom surface of the base, thereby substantially preventing contact between the bottom surface of the base and the flat surface. The feet may be knobs, prongs, or protrusions of any kind. This embodiment permits air flow between the base and the flat surface, and at least in part, prevents the components that may be stored or located in or on the base from overheating. This embodiment may also provide for ornamentation of the feet and the apparatus. In some versions, the one or more feet may comprise soft pads so as to decrease or prevent the feet from scratching the flat surface. In some versions, the one or more feet may comprise one or more height adjustment means, e.g., the one or more feet comprise female threading to receive male threads that protrude from the base; alternatively, the one or more feet comprise protruding male threads that are received by female threads residing in the base. These versions enable a user of the apparatus to raise and lower the apparatus vis-a-vis the flat surface so as to increase the air flow between the two. Additionally, if the apparatus is placed on a non-level or contoured surface, one or more height adjustment means may be raised or lowered more or less than other one or more height adjustment means, so as to level the apparatus evenly with respect to gravity. In some versions, the one or more feet may be removed such that the base may sit immediately on a surface. In these versions, the one or more feet may also be replaced, either in case of damage, or in order to provide for a diversity in shape, size, or ornamentation.

The walls may be perpendicularly disposed with respect to the bottom 116. In one embodiment, at least one wall 103 is at an angle of between zero and ninety degrees from the bottom 116. This range of angle may provide an apparatus that may match or complement of bottom of a lamp having an angled or beveled base.

In one embodiment, one or more walls comprise thread rims, which threadably engage with threads disposed on the base and/or the lid. In yet another embodiment, one or more walls may attach to the base and/or the lid by means of one or more slide protrusions. A slide protrusion comprises an edge that is perpendicularly disposed on an extension, and may be coupled with a recess, where the recess has an exposed first opening sufficiently large to receive the entire slide protrusion and extension, and a concealed second opening, such that the slide protrusion may be slided into the second opening, while the extension sticks out of the first opening. In an additional embodiment, one or more walls are molded as one piece with the base and/or the lid.

In one embodiment, the apparatus comprises a wireless charging pad. In one version, the charging pad may be positioned beneath the lid. In another version, the apparatus may comprise a sliding shelf, that shelf comprising a wireless charging pad. This sliding shelf has one or more edges that mate with one or more brackets structurally disposed in the interior of the apparatus. In one version a tab or gripping region on an exposed side of the shelf enables a human finger to contactedly slide the shelf substantially out of the apparatus. In another version, the sliding shelf is electronically engageable using the same mechanical parts that are used for the ejecting action of CD or DVD players.

The following examples pertain to further embodiments.

Example 1 is an apparatus comprising a base, a lid, one or more walls, and an interior; where the base is attached to one or more of the one or more walls and the lid is attached to one or more of the one or more walls; where the interior is bounded at least partially by the base, the lid, and the one or more walls; where the base comprises a bottom surface and the lid comprises a top surface, the top surface being sufficiently flat and greater than three inches in diameter; where the lid is disposed above the base; and where at least one USB port is disposed on one of the one or more walls.

In Example 2, the subject matter of Example 1 can include, wherein the lid is weight bearing and shaped as a circle or a square to be disposed under and support a lamp base.

In Example 3, the subject matter of Example 1 can include, wherein at least one wall comprises at least one opening that provides access to the interior.

In Example 4, the subject matter of Example 1 can include, wherein at least one perimeteral design element is disposed to visually mask at least one USB port.

In Example 5, the subject matter of Example 1 can include, wherein at least on electrical outlet is disposed on one or more of the one or more walls.

In Example 6, the subject matter of Example 1 can include, wherein a button that controls a power source is disposed on one or more of the one or more walls.

In Example 7, the subject matter of Example 6 can include, wherein the button controls the power for an outlet to power an electrical device.

In Example 8, the subject matter of Example 2 can include, wherein the top surface of the lid is greater than five inches in diameter.

In Example 9, the subject matter of Example 2 can include, wherein the top surface of the lid comprises one or more areas of uneven texture to prevent a lamp base from sliding.

In Example 10, the subject matter of Example 1 can include, wherein the apparatus comprises at least one compartment.

In Example 11, the subject matter of Example 10 can include, wherein at least one wall comprises an opening that provides access to at least one compartment.

In Example 12, the subject matter of Example 10 can include, wherein at least one compartment is open to the bottom of the apparatus.

In Example 13, the subject matter of Example 10 can include, wherein at least one compartment is formed in the bottom and encroaches into the interior.

In Example 14, the subject matter of Example 10 can include, wherein at least one compartment is disposed in a substantially circumferential channel inside at least one wall.

In Example 15, the subject matter of Example 10 can include, wherein at least one compartment is configured to house excess cable used with the apparatus.

Example 16 is an apparatus comprising a base, a lid, one or more walls, an interior and a compartment; where the base is attached to one or more of the one or more walls and the lid is attached to one or more of the one or more walls; where the interior is bounded at least partially by the base, the lid, and the one or more walls; where the base comprises a bottom surface and the compartment is formed in the bottom surface; where the lid comprises a top surface and the top surface being sufficiently flat and greater than three inches in diameter; where the lid is disposed above the base; where at least one USB port and one outlet are disposed on one or more walls; where at least one power source providing electricity to the at least one USB port is located in the interior; and where a button that controls at least one power source is disposed on the one or more walls.

In Example 17, the subject matter of Example 16 can include, wherein at least one wall comprises an opening that provides access to the compartment.

In Example 18, the subject matter of Example 16 can include, wherein at least one compartment is configured to house excess cable used with the apparatus.

Example 19 is an apparatus comprising a base, a lid, one or more walls, an interior and a compartment; where the base is attached to one or more of the one or more walls and the lid is attached to one or more of the one or more walls; where the interior is bounded at least partially by the base, the lid, and the one or more walls and houses electronic components; where the base comprises a bottom surface and the compartment is formed in the bottom surface; where the compartment is configured to house excess cable used with the apparatus; where the lid comprises a top surface and the top surface being sufficiently flat and shaped as a circle or a square to be disposed under and weight bearing to support a lamp base that is greater than three inches across; where the lid is disposed above the base; where a plurality of USB ports are disposed on a left side and a right side on one or more walls, and a plurality of outlets are disposed on a back side of one or more walls; where at least one power source providing electricity to the plurality of USB ports and the plurality of outlets is housed in the interior; where a power switch that controls at least one power source is disposed on the one or more walls, and where a design element is disposed horizontally around the one or more walls at a height substantially equal to the height of the plurality of USB ports, the design element disposed between at least one of the plurality of outlets and at least one of the plurality of USB ports and between at least one of the plurality of USB ports and the power switch.

In Example 20, the subject matter of Example 19 can include, wherein the design element is a groove.

It is to be understood that the above description is intended to be illustrative, and not restrictive. For example, the above-described embodiments may be used in combination with each other. Many other embodiments will be apparent to those of skill in the art upon reviewing the above description. The scope of the invention therefore should be determined with reference to the appended claims, along with the full scope of equivalents to which such claims are entitled.

1. The apparatus comprises a base, a lid, one or more walls, and an interior; where the base is attached to one or more of the one or more walls and the lid is attached to one or more of the one or more walls; where the interior is bounded at least partially by the base, the lid, and the one or more walls; where the base comprises a bottom surface and the lid comprises a top surface, the top surface being sufficiently flat and greater than three inches in diameter; where the lid is disposed above the base; and where at least one USB port is disposed on one of the one or more walls.

2. The apparatus in claim 1, wherein the lid is weight bearing and shaped as a circle or a square to be disposed under and support a lamp base.

3. The apparatus in claim 1, wherein at least one wall comprises at least one opening that provides access to the interior.

4. The apparatus in claim 1, wherein at least one perimeteral design element is disposed to visually mask at least one USB port.

5. The apparatus in claim 1, wherein at least on electrical outlet is disposed on one or more of the one or more walls.

6. The apparatus in claim 1, wherein a button that controls a power source is disposed on one or more of the one or more walls.

7. The apparatus in claim 6, wherein the button controls the power for an outlet to power an electrical device.

8. The apparatus in claim 2, wherein the top surface of the lid is greater than five inches in diameter.

9. The apparatus in claim 2, wherein the top surface of the lid comprises one or more areas of uneven texture to prevent a lamp base from sliding.

10. The apparatus in claim 1, wherein the apparatus comprises at least one compartment.

11. The apparatus in claim 10, wherein at least one wall comprises an opening that provides access to at least one compartment.

12. The apparatus in claim 10, wherein at least one compartment is open to the bottom of the apparatus.

13. The apparatus in claim 10, wherein at least one compartment is formed in the bottom and encroaches into the interior.

14. The apparatus in claim 10, wherein at least one compartment is disposed in a substantially circumferential channel inside at least one wall.

15. The apparatus in claim 10, wherein at least one compartment is configured to house excess cable used with the apparatus.

16. The apparatus comprises a base, a lid, one or more walls, an interior and a compartment; where the base is attached to one or more of the one or more walls and the lid is attached to one or more of the one or more walls; where the interior is bounded at least partially by the base, the lid, and the one or more walls; where the base comprises a bottom surface and the compartment is formed in the bottom surface; where the lid comprises a top surface and the top surface being sufficiently flat and greater than three inches in diameter; where the lid is disposed above the base; where at least one USB port and one outlet are disposed on one or more walls; where at least one power source providing electricity to the at least one USB port is located in the interior; and where a button that controls at least one power source is disposed on the one or more walls.

17. The apparatus in claim 16, wherein at least one wall comprises an opening that provides access to the compartment.

18. The apparatus in claim 16, wherein at least one compartment is configured to house excess cable used with the apparatus.

19. The apparatus comprises a base, a lid, one or more walls, an interior and a compartment; where the base is attached to one or more of the one or more walls and the lid is attached to one or more of the one or more walls; where the interior is bounded at least partially by the base, the lid, and the one or more walls and houses electronic components; where the base comprises a bottom surface and the compartment is formed in the bottom surface; where the compartment is configured to house excess cable used with the apparatus; where the lid comprises a top surface and the top surface being sufficiently flat and shaped as a circle or a square to be disposed under and weight bearing to support a lamp base that is greater than three inches across; where the lid is disposed above the base; where a plurality of USB ports are disposed on a left side and a right side on one or more walls, and a plurality of outlets are disposed on a back side of one or more walls; where at least one power source providing electricity to the plurality of USB ports and the plurality of outlets is housed in the interior; where a power switch that controls at least one power source is disposed on the one or more walls, and where a design element is disposed horizontally around the one or more walls at a height substantially equal to the height of the plurality of USB ports, the design element disposed between at least one of the plurality of outlets and at least one of the plurality of USB ports and between at least one of the plurality of USB ports and the power switch.

20. The apparatus in claim 19, wherein the design element is a groove.
